(19) United States
(12) Patent Application Publication
(10) Pub. No.: US 2006/0055448 A1
(43) Pub. Date: Mar. 16, 2006

(54) Voltage generator

(75) Inventor: Youichi Tobita, Tokyo (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: MITSUBISHI DENKI KABUSHIKI KAISHA, Tokyo (JP)

(21) Appl. No.: 11/224,142

(22) Filed: Sep. 13, 2005

(30) Foreign Application Priority Data
Sep. 14, 2004 (JP) 2004-266686
Aug. 11, 2005 (JP) 2005-232778

(51) Int. Cl. G11C 5/14

(52) U.S. Cl. 327/530

(57) ABSTRACT

A PMOS transistor has its source connected to a first node at which the voltage level varies from VDD to 2VDD and its drain connected to the drain of each of cross-connected NMOS transistors at a second node. The NMOS transistors have their sources connected to one ends of capacitive elements charged up to 2VDD, respectively. The cross-connected NMOS transistors keeps the voltage at the second node at a constant value (2VDD) regardless of signals input to the other ends of the capacitive elements, respectively. The PMOS transistor can be turned off by applying a voltage of 2VDD to the gate. Consequently, the PMOS transistor has a maximum reverse voltage (gate-to-source voltage in the off state) of VDD.

### BACKGROUND OF THE INVENTION

1. Field of the Invention

The present invention relates to a voltage generator, and more particularly, to a voltage generator using a thin film transistor manufactured by low-temperature poly-silicon technology.

2. Description of the Background Art

A conventional voltage generator combines a plurality of capacitive elements and a plurality of transistors, to generate a predetermined voltage. For instance, a voltage generator for raising an input voltage of VDD to output an output voltage of 3VDD is configured as described below.

That is, the voltage generator includes a first capacitive element having one end connected to an input terminal to which an input voltage is input, a first PMOS transistor having its source connected to the one end of the first capacitive element, a second capacitive element having one end connected to the drain of the first PMOS transistor, a second PMOS transistor having its source connected to the one end of the second capacitive element and a third capacitive element having its one end connected to the drain of the second PMOS transistor and an output terminal from which an output voltage is output.

The voltage generator generates a voltage of 3VDD by the following operation. First, the first capacitive element is charged up to VDD with the first PMOS transistor maintained in the off state. Next, a voltage of VDD is applied to the other end of the first capacitive element to raise the voltage at the one end of the first capacitive element from VDD to 2VDD. Further, the first PMOS transistor is turned on to flow a load current from the first capacitive element to the second capacitive element, so that the second capacitive element is charged up to 2VDD.

Next, the first PMOS transistor is turned off, and a voltage of VDD is applied to the other end of the second capacitive element. Then, the voltage at the one end of the second capacitive element is raised up to 3VDD. Next, the second PMOS transistor is turned on to flow a load current from the second capacitive element to the third capacitive element, so that the third capacitive element is charged up to 3VDD. Accordingly, it is possible to obtain an output voltage of 3VDD from the output terminal connected to the one end of the third capacitive element.

The prior art related to the present invention is disclosed in Japanese Patent Application Laid-Open No. 63-290159 (1988).

However, to hold the first PMOS transistor off when the voltage at the one end of the second capacitive element is raised up to 3VDD, a voltage of 3VDD needs to be applied to the gate of the first PMOS transistor. At this time, the voltage at the one end of the first capacitive element connected to the source of the first PMOS transistor is VDD. Accordingly, a large gate-to-source voltage (2VDD in the above example) (hereinafter, a gate-to-source voltage in the off state may be referred to as a “reverse voltage”) is applied to the first PMOS transistor in the off state.

In the case of using thin film transistors manufactured by low-temperature poly-silicon technology as the first and second PMOS transistors, it is known that thin film transistors are degraded more significantly as the reverse voltage rises (cf. “Hot Carrier Degradation in Low-temperature Poly-Si Thin Film Transistors” by Yukiharu Uraoka, et al., preprints for workshop 2002, the Chugoku and Shikoku chapter, the Japan Society of Applied Physics).

More specifically, when the gate-to-source voltage rises when a thin film transistor is in the off state, an on-state current in the thin film transistor decreases depending on the time during which the reverse voltage is applied. As a result, a problem arises in that the thin film transistor is degraded in drive capability, so that a predetermined voltage is not generated.

### SUMMARY OF THE INVENTION

It is an object of the present invention to provide a voltage generator for decreasing a reverse voltage applied to thin film transistors, thereby controlling degradation with time of the thin film transistors in on-state current.

According to a first aspect of the present invention, the voltage generator includes a plurality of unit voltage generation circuits connected in cascade. One of the plurality of unit voltage generation circuits includes a first field effect transistor, a first capacitive element, a second field effect transistor and a second capacitive element. The first field effect transistor has one terminal to which an input voltage is input. The first capacitive element has one end connected to the other terminal of the first field effect transistor. The second field effect transistor has one terminal connected to the one end of the first capacitive element. The second capacitive element has one end connected to the other terminal of the second field effect transistor from which an output voltage is output.

When the first and second field effect transistors constituting a unit voltage generation circuit are in the off state, it is possible to reduce the voltage difference between the one and the other terminals of each of the transistors. Consequently, when the present invention is applied to a voltage generator manufactured using thin film transistors, each of the first and second field effect transistors can be prevented from being degraded in on-state current with time.

According to a second aspect of the invention, the voltage generator includes a first field effect transistor having one terminal to which an input voltage is input, a first capacitive element having one end connected to the other terminal of the first field effect transistor, a second field effect transistor having one terminal connected to the one end of the first capacitive element, a second capacitive element having one end connected to the other terminal of the second field effect transistor from which an output voltage is output, and a third field effect transistor being cross-connected to the first field effect transistor. The second field effect transistor when conducting carries a voltage between a control terminal and the one terminal thereof having an absolute value almost equal to an absolute value of the output voltage.

With the cross-connection between the first and third field effect transistors, the first field effect transistor can be completely turned off when supplying a current from the first capacitive element to a node which connects the first and second field effect transistors. This can increase the efficiency in voltage generation.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating the configuration of a voltage generator according to a first preferred embodiment of the present invention;

FIG. 2 is a timing chart of the voltage generator according to the first preferred embodiment;

FIG. 3 is a circuit diagram illustrating the configuration of a voltage generator according to a second preferred embodiment of the invention;

FIG. 4 is a timing chart of the voltage generator according to the second preferred embodiment;

FIG. 5 is a circuit diagram illustrating the configuration of a voltage generator according to a third preferred embodiment of the invention;

FIG. 6 is a circuit diagram illustrating the configuration of a voltage generator according to a fourth preferred embodiment of the invention;

FIG. 7 is a circuit diagram illustrating the configuration of a voltage generator according to a fifth preferred embodiment of the invention;

FIG. 8 is a timing chart of the voltage generator according to the fifth preferred embodiment;

FIG. 9 is a circuit diagram illustrating the configuration of a voltage generator according to a sixth preferred embodiment of the invention;

FIG. 10 is a timing chart of the voltage generator according to the sixth preferred embodiment;

FIG. 11 is a circuit diagram illustrating the configuration of a voltage generator according to a seventh preferred embodiment of the invention; and

FIG. 12 is a circuit diagram illustrating the configuration of a voltage generator according to an eighth preferred embodiment of the invention.

### DESCRIPTION OF THE PREFERRED EMBODIMENTS

### First Preferred Embodiment

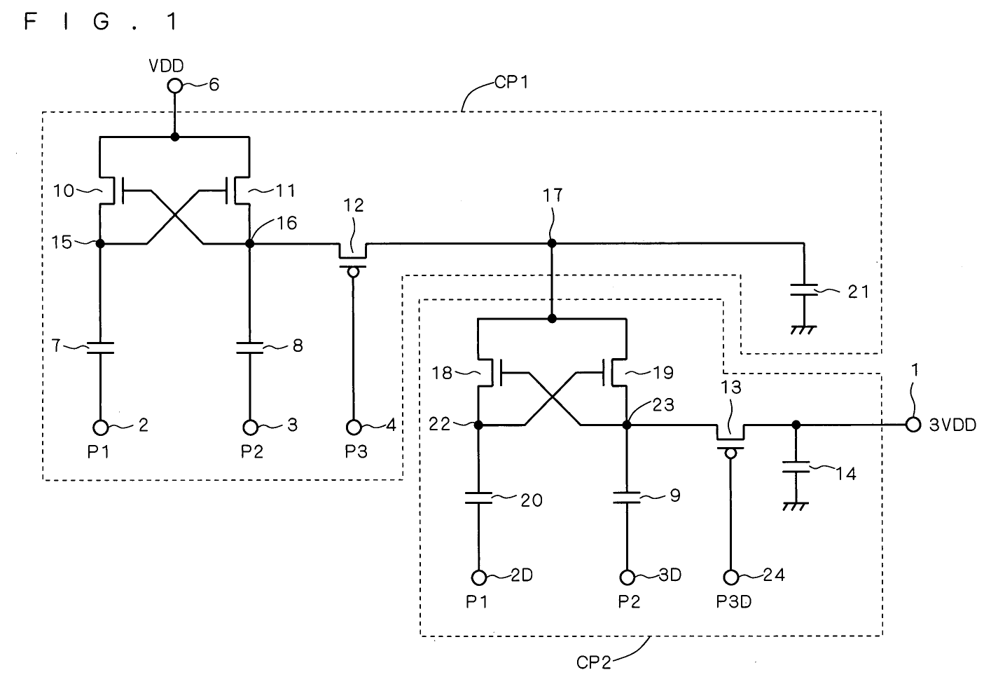

FIG. 1 is a circuit diagram illustrating the configuration of a voltage generator according to a first preferred embodiment of the present invention. The voltage generator according to the present embodiment includes a unit voltage generation circuit CP1 and a unit voltage generation circuit CP2 connected to the unit voltage generation circuit CP1 at a node 17.

First, the configuration of the unit voltage generation circuit CP1 will be described. An NMOS transistor 10 (third field effect transistor) has its drain (one terminal serving as a current input terminal) connected to a terminal 6 and its source (the other terminal serving as a current output terminal) connected to one end of a capacitive element 7 and the gate (a control terminal serving as a current control terminal) of an NMOS transistor 11 (first field effect transistor) at a node 15. A voltage of VDD (input voltage) is input to the terminal 6.

The capacitive element 7 has its other end connected to a terminal 2, to which a signal P1 is input. The NMOS transistor 11 has its drain connected to the terminal 6 and its source connected to one end of a capacitive element 8 (first capacitive element) and the gate of the NMOS transistor 10 at a node 16. The capacitive element 8 has its other end connected to a terminal 3, to which a signal P2 is input. The NMOS transistors 10 and 11 constitute a cross connection.

A PMOS transistor 12 (second field effect transistor) has its source connected to the node 16 and its drain connected to one end of a capacitive element 21 (second capacitive element) at the node 17. The PMOS transistor 12 has its gate connected to a terminal 4, to which a signal P3 is input. The capacitive element 21 has its other end grounded. The capacitive element 21 is a stabilizing capacitive element for stabilizing the voltage level at the node 17, and it may be omitted when a light load is connected to a terminal 1 to be described later.

Next, the unit voltage generation circuit CP2 will be described. An NMOS transistor 18 has its drain connected to the node 17 and its source connected to one end of a capacitive element 20 and the gate of an NMOS transistor 19 at a node 22. The capacitive element 20 has its other end connected to a terminal 2D, to which the signal P1 is input.

The NMOS transistor 19 has its drain connected to the node 17 and its source connected to one end of a capacitive element 9 and the gate of an NMOS transistor 18 at a node 23. The capacitive element 9 has its other end connected to a terminal 3D, to which the signal P2 is input. The NMOS transistors 18 and 19 constitute a cross connection.

A PMOS transistor 13 has its source connected to the node 23 and its drain connected to the terminal 1 and one end of a capacitive element 14. The capacitive element 14 has its other end grounded. The PMOS transistor 13 has its gate connected to a terminal 24, to which a signal P3D is input.

Each of the signals P1, P2, P3 and P3D is a control signal (repetitive signal) for controlling the voltage generator.

Now, an operation of the voltage generator according to the present embodiment will be described. For the sake of simplicity, an operation in a steady state with no load will be described hereinbelow. In the steady state, the capacitive elements 7 and 8 are both charged with a voltage of VDD. The capacitive elements 9, 20 and 21 are all charged with a voltage of 2VDD. The capacitive element 14 is charged with a voltage of 3VDD.

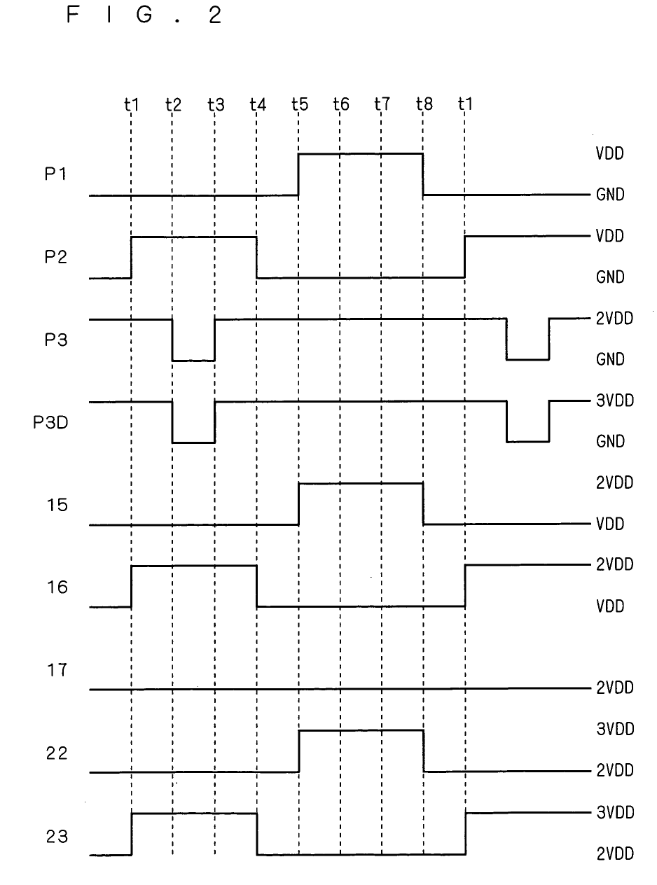

FIG. 2 is a timing chart showing the operation of the voltage generator according to the present embodiment. The signal waveforms of signals P1, P2, P3 and P3D and voltage waveforms at the nodes 15, 16, 17, 22 and 23 are shown respectively.

First, the operation of the unit voltage generation circuit CP1 will be described. At time t1, the signal P2 rises from GND to VDD with the signal P1 kept at GND (0V). At this time, the voltage at the node 16 rises from VDD to 2VDD. When the voltage at the node 16 reaches 2VDD, the gate-to-source voltage in the NMOS transistor 10 becomes VDD, and the NMOS transistor 10 transitions to the on state.

Since the voltage level at the terminal 6 is VDD, the voltage level at the node 15 is VDD. Accordingly, the voltage level at the node 15 is compensated for up to VDD even when a leakage current causes a voltage drop at the node 15.

Also, a voltage of VDD is applied to the gate of the NMOS transistor 11. The gate-to-source voltage in the NMOS transistor 11 is −VDD, and the NMOS transistor 11 remains in the off state. Thus, it is possible to prevent a leakage current from flowing from the node 16 to the terminal 6 and the voltage level at the node 16 from dropping.

Next, at time t2, the voltage level of the signal P3 transitions from 2VDD to GND. A voltage of 2VDD of the signal P3 is generated by a driving circuit (not shown) using, for example, the output voltage of 2VDD from the capacitive element 21 as a supply voltage. This also applies to a voltage of 3VDD of the signal P3D which will described later. The gate-to-source voltage in the PMOS transistor 12 becomes −2VDD, and the PMOS transistor 12 transitions from the off state to the on state. A load current normally flows from the node 16 to the capacitive element 21 via the PMOS transistor 12. Then, the capacitive element 21 is charged up to 2VDD. However, a load current does not flow because the operation in the no-loaded steady state is considered now and the capacitive element 21 has been charged up to 2VDD. Here, the PMOS transistor 12 when conducting carries a gate-to-source voltage having an absolute value almost equal to an absolute value of the output voltage from the capacitive element 21.

Next, at time t3, the voltage level of the signal P3 transitions from GND to 2VDD. As a result, the gate-to-source voltage in the PMOS transistor 12 becomes 0V, and the PMOS transistor 12 transitions from the on state to the off state. Therefore, the voltage level at the node 17 is kept at 2VDD even when the voltage level at the node 16 varies.

At time t4, the voltage level of the signal P2 transitions from VDD to GND, and the voltage level at the node 16 transitions from 2VDD to VDD. At this time, the PMOS transistor 12 is in the off state with a voltage of 2VDD being applied to its gate and the gate-to-source voltage being kept at VDD. Since the PMOS transistor 12 is in the off state, there is no possibility that current will flow from the node 17 to the node 16 via the PMOS transistor 12 to cause a voltage drop at the node 17.

At time t5, the voltage level of the signal P1 transitions from GND to VDD. As the capacitive element 7 has been charged up to VDD, the voltage level at the node 15 transitions from VDD to 2VDD. As a result, the gate-to-source voltage in the NMOS transistor 11 becomes VDD, and the NMOS transistor 11 transitions to the on state. The node 16 is connected to the terminal 6 via the NMOS transistor 11. Accordingly, a load current normally flows from the terminal 6 to the node 16 to charge the capacitive element 8 up to VDD, so that the voltage level at the node 16 becomes VDD. However, the voltage level at the node 16 does not vary because the operation in the no-loaded steady state is considered now and the capacitive element 8 has been charged up to VDD.

At time t6 and time t7, the state at time t5 is maintained. At time t8, the voltage level of the signal P1 transitions from VDD to GND. The voltage level at the node 15 transitions from 2VDD to VDD. Then, the gate-to-source voltage in the NMOS transistor 11 becomes 0V, so that the NMOS transistor 11 is turned off.

Now, the operation of the unit voltage generation circuit CP2 will be described. At time t1, the voltage level of the signal P2 rises from GND to VDD, and then, the voltage at the node 23 rises from VDD to 3VDD. When the voltage at the node 23 reaches 3VDD, the gate-to-source voltage in the NMOS transistor 18 becomes VDD, so that the NMOS transistor 18 transitions to the on state.

Since the voltage level at the node 17 is 2VDD, the voltage level at the node 22 is also 2VDD. Therefore, the voltage level at the node 22 is compensated for up to 2VDD even when a leakage current causes a voltage drop at the node 22.

The gate of the NMOS transistor 19 is connected to the node 22. As the voltage level at the node 22 is 2VDD, the NMOS transistor 19 is kept in the off state even when the voltage level at the node 23 rises to 3VDD. Therefore, the voltage level at the node 17 is kept at 2VDD even when the voltage level at the node 23 rises.

At time t2, the voltage level of the signal P3D transitions from 3VDD to GND. As a result, the gate-to-source voltage in the PMOS transistor 13 becomes −3VDD, so that the PMOS transistor 13 transitions from the off state to the on state. A load current normally flows from the node 23 to the capacitive element 14 via the PMOS transistor 13. Then, the capacitive element 14 is charged up to 3VDD. However, an output voltage of 3VDD is output from the terminal 1 because the operation in the no-loaded steady state is considered now and the capacitive element 14 has been charged up to 3VDD.

At time t3, the voltage level of the signal P3D transitions from GND to 3VDD. As a result, the gate-to-source voltage in the PMOS transistor 13 becomes 0V, so that the PMOS transistor 13 transitions from the on state to the off state. Therefore, the voltage level at the terminal 1 is kept at 3VDD even when the voltage level at the node 23 varies.

At time t4, the voltage level of the signal P2 transitions from VDD to GND. Then, the voltage level at the node 23 transitions from 3VDD to 2VDD. A voltage of 3VDD is applied to the gate of the PMOS transistor 13, and the gate-to-source voltage in the PMOS transistor 13 is VDD. Therefore, the PMOS transistor 13 is in the off state, and there is no possibility that current will flow from the terminal 1 to the node 23 via the PMOS transistor 13 to cause a voltage drop at the terminal 1.

Next, at time t5, the voltage level of the signal P1 transitions from GND to VDD. Since the capacitive element 20 has been charged to up 2VDD, the voltage level at the node 22 transitions from 2VDD to 3VDD. As a result, the gate-to-source voltage in the NMOS transistor 19 becomes VDD, and the NMOS transistor 19 transitions to the on state. The node 23 is connected to the node 17 via the NMOS transistor 19. Therefore, a load current normally flows from the node 17 to the node 23, and the capacitive element 9 is charged up to 2VDD, so that the voltage level at the node 23 becomes 2VDD. However, the voltage level at the node 23 does not vary because the operation in the no-loaded steady state is considered now and the capacitive element 9 has been charged up to 2VDD.

Since the NMOS transistor 18 is in the off state even when the voltage level at the node 22 transitions from 2VDD to 3VDD, there is no possibility that the voltage level at the node 17 will transition to 3VDD.

At time t6 and time t7, the state at time t5 is maintained. At time t8, the voltage level of the signal P1 transitions from VDD to GND. The voltage level at the node 22 transitions from 3VDD to 2VDD. Then, the gate-to-source voltage in the NMOS transistor 19 becomes 0V, so that the NMOS transistor 19 is turned off.

In the voltage generator according to the present embodiment, the NMOS transistors 18 and 19 are cross-connected, so that the voltage level at the node 17 is kept at 2VDD even when the voltage levels at the nodes 22 and 23 rise. The voltage level at the node 16 ranges from VDD to 2VDD. Therefore, to turn the PMOS transistor 12 off, a voltage of 2VDD may be applied to the gate of the PMOS transistor 12. Accordingly, the reverse voltage in the PMOS transistor 12 becomes VDD even when the voltage level at the node 16 transitions to VDD.

Further, the voltage level at the terminal 1 is kept at 3VDD, and the voltage level at the node 23 ranges from 2VDD to 3VDD. Therefore, the PMOS transistor 13 can be turned off by applying a voltage of 3VDD to the gate. Then, the reverse voltage in the PMOS transistor 13 becomes VDD even when the voltage level at the node 23 transitions to 2VDD.

Since the reverse voltage applied to the PMOS transistors 12 and 13 can be made VDD, it is possible to prevent degradation of the PMOS transistors 12 and 13 in drive capability which would be caused by a large reverse voltage.

The voltage levels of VDD and GND have been used in the above description for the sake of simplicity. Indicating a reference voltage as VR and a voltage amplitude of the signal P2 as VW, then, an output voltage V1 output from the terminal 1 is generally expressed as: V1=VR+2·VW. In the example shown in FIG. 1, the reference voltage VR is VDD and the voltage amplitude VW is VDD, and therefore, the output voltage V1 becomes 3VDD.

Further, in FIG. 1, the voltage VDD input to the terminal 6 and the capacitive elements 8 and 9 serve to supply a load current. The signal P2 is thus required to have current drive capability. Therefore, for instance, the signal P2 is generated by a main power of an LSI with the high (H) level set at VDD and the low (L) level set at 0V.

The signals P1 and P2 may not necessarily identical in voltage levels. The signals P1 and P2 are used for driving the capacitive elements 20 and 9, respectively, however, other signals having the same phase relationship as that between the signals P1 and P2 may be used.

Further, the number of unit voltage generation circuits may be increased to generate a higher output voltage without increasing the reverse voltage.

### Second Preferred Embodiment

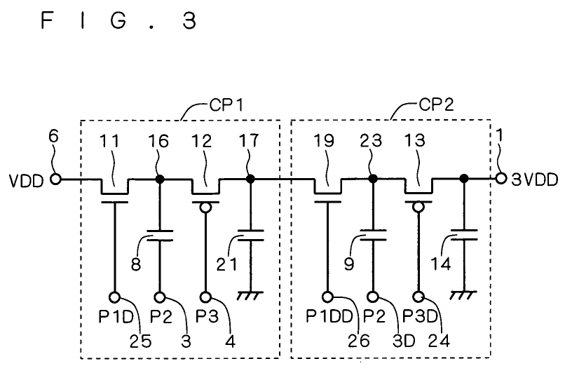

FIG. 3 is a circuit diagram illustrating the configuration of a voltage generator according to a second preferred embodiment. The voltage generator according to the present embodiment replaces the cross connection formed by the NMOS transistors 10 and 11 and that formed by the NMOS transistors 18 and 19 of the voltage generator according to the first preferred embodiment (see FIG. 1) by the NMOS transistor 11 (first field effect transistor) and NMOS transistor 19 (first field effect transistor), respectively.

A signal having the same voltage level as that applied in the first preferred embodiment is applied to the gate of each of the NMOS transistors 11 and 19. More specifically, in the first preferred embodiment, the signal P1 transitions form GND to VDD, so that a voltage which transitions from VDD to 2VDD is applied to the gate of the NMOS transistor 11.

In the present embodiment, the voltage generator is configured such that a signal P1D which transitions from VDD to 2VDD having the same phase as the signal P1 is input to the gate of the NMOS transistor 11. Similarly, a signal which transitions from 2VDD to 3VDD having the same phase as the signal P1 is input to the NMOS transistor 19. The rest of the configuration is the same as that of the first preferred embodiment, and the same elements are indicated by the same reference characters, repeated explanation of which is thus omitted here.

First, the unit voltage generation circuit CP1 according to the present embodiment will be described. The NMOS transistor 11 has its drain connected to the terminal 6. A voltage of VDD is input to the terminal 6. The NMOS transistor 11 has its source connected to the source of the PMOS transistor 12 and one end of the capacitive element 8 at the node 16. The capacitive element 8 has its other end connected to the terminal 3, to which the signal P2 is input. The NMOS transistor 11 has its gate connected to a terminal 25, to which the signal P1D is input.

The PMOS transistor 12 has its drain connected to the one end of the capacitive element 21 and the drain of the NMOS transistor 19 at the node 17. The capacitive element 21 has its other end grounded. The PMOS transistor 12 has its gate connected to the terminal 4, to which the signal P3 is input.

Next, the unit voltage generation circuit CP2 will be described. The NMOS transistor 19 has its source connected to the source of the PMOS transistor 13 and the one end of the capacitive element 9 at the node 23. The capacitive element 9 has its other end connected to the terminal 3D, to which the signal P2 is input. The NMOS transistor 19 has its gate connected to a terminal 26, to which a signal P1DD is input.

The PMOS transistor 13 has its drain connected to the terminal 1 and the one end of the capacitive element 14. The capacitive element 14 has its other end grounded. The PMOS transistor 13 has its gate connected to the terminal 24, to which the signal P3D is input.

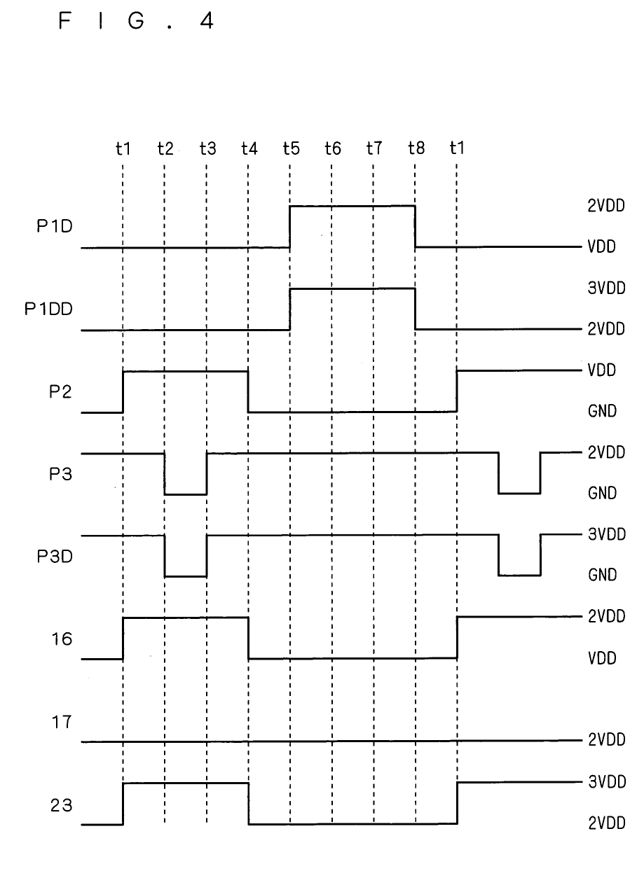

An operation of the voltage generator according to the present embodiment will now be described. FIG. 4 is a timing chart of the voltage generator according to present embodiment, showing the signal waveforms of signals P1D, P1DD, P2, P3 and P3D and voltage waveforms at the nodes 16, 17 and 23.

For the sake of simplicity, an operation in the no-loaded steady state will be described hereinbelow. In the no-loaded steady state, the capacitive element 8 is charged up to VDD. The capacitive elements 9 and 21 are charged up to 2VDD. The capacitive element 14 is charged up to 3VDD. FIG. 4 shows one period of each of the signals.

First, the operation of the unit voltage generation circuit CP1 will be described. At time t1, the signal P2 rises from GND to VDD. At this time, the voltage at the node 16 rises from VDD to 2VDD. The signal P1D having a voltage level of VDD is input from the terminal 25 to the gate of the NMOS transistor 11. Then, the gate-to-source voltage in the NMOS transistor 11 becomes −VDD, and the NMOS transistor 11 is maintained in the off state. Therefore, there is no possibility that a leakage current will flow from the node 16 to the terminal 6 to cause a voltage drop at the node 16.

Next, at time t2, the voltage level of the signal P3 transitions from 2VDD to GND. The gate-to-source voltage in the PMOS transistor 12 becomes −2VDD, and the PMOS transistor 12 transitions from the off state to the on state. A load current normally flows from the node 16 to the capacitive element 21 via the PMOS transistor 12. Then, the capacitive element 21 is charged up to 2VDD. However, a load current does not flow because the operation in the no-loaded steady state is considered now and the capacitive element 21 has been charged up to 2VDD.

Next, at time t3, the voltage level of the signal P3 transitions from GND to 2VDD. As a result, the gate-to-source voltage in the PMOS transistor 12 becomes 0V, and the PMOS transistor 12 transitions from the on state to the off state. Therefore, the voltage level at the node 17 is kept at 2VDD even when the voltage level at the node 16 varies.

At time t4, the voltage level of the signal P2 transitions from VDD to GND, and the voltage level at the node 16 transitions from 2VDD to VDD. At this time, the PMOS transistor 12 is in the off state. Therefore, there is no possibility that current will flow from the node 17 to the node 16 via the PMOS transistor 12 to cause a voltage drop at the node 17.

At time t5, the voltage level of the signal P1D transitions from VDD to 2VDD. As the capacitive element 8 has been charged up to VDD, the gate-to-source voltage in the NMOS transistor 11 becomes VDD, and the NMOS transistor 11 transitions to the on state. The node 16 is connected to the terminal 6 via the NMOS transistor 11. Accordingly, a load current normally flows from the terminal 6 to the node 16 to charge the capacitive element 8 up to VDD, so that the voltage level at the node 16 becomes VDD. However, the voltage level at the node 16 does not vary because the operation in the no-loaded steady state is considered now and the capacitive element 8 has been charged up to VDD.

At time t6 and time t7, the state at time t5 is maintained. At time t8, the voltage level of the signal P1D transitions from 2VDD to VDD. The gate-to-source voltage in the NMOS transistor 11 becomes 0V, so that the NMOS transistor 11 is turned off.

Now, the operation of the unit voltage generation circuit CP2 will be described. At time t1, the voltage level of the signal P2 rises from GND to VDD, then, the voltage at the node 23 rises from 2VDD to 3VDD.

Here, at time t1, the signal P1DD having a voltage level of 2VDD is input to the gate of the NMOS transistor 19. Then, the gate-to-source voltage in the NMOS transistor 19 becomes −VDD, so that the NMOS transistor 19 is turned off. Therefore, there is no possibility that a load current will flow from the node 23 to the node 17 through the NMOS transistor 19 to cause a voltage drop at the node 23.

At time t2, the voltage level of the signal P3D transitions from 3VDD to GND. As a result, the gate-to-source voltage in the PMOS transistor 13 becomes −3VDD, so that the PMOS transistor 13 transitions from the off state to the on state. Accordingly, a load current normally flows from the node 23 to the capacitive element 14 through the PMOS transistor 13. Then, the capacitive element 14 is charged up to 3VDD. However, a load current does not flow because the operation in the no-loaded steady state is considered now and the capacitive element 14 has been charged up to 3VDD. Further, since the capacitive element 14 has been charged up to 3VDD, a voltage of 3VDD is output from the terminal 1.

At time t3, the voltage level of the signal P3D transitions from GND to 3VDD. As a result, the gate-to-source voltage in the PMOS transistor 13 becomes 0V, so that the PMOS transistor 13 transitions from the on state to the off state. Therefore, the voltage level at the terminal 1 is kept at 3VDD even when the voltage level at the node 23 varies.

At time t4, the voltage level at the node 23 transitions from 3VDD to 2VDD. A voltage of 3VDD is applied to the gate of the PMOS transistor 13, and the PMOS transistor 13 is in the off state. Therefore, there is no possibility that current will flow from the terminal 1 to the node 23 via the PMOS transistor 13 to cause a voltage drop at the terminal 1. Further, the voltage level at the node 23 drops to 2VDD, so that the gate-to-source voltage (reverse voltage) in the PMOS transistor 13 becomes VDD.

At time t5, the voltage level of the signal P1DD transitions from 2VDD to 3VDD. Since the capacitive element 9 has been charged up to 2VDD, the gate-to-source voltage in the NMOS transistor 19 becomes VDD, so that the NMOS transistor 19 transitions to the on state. The node 23 is connected to the node 17 via the NMOS transistor 19. Accordingly, a load current normally flows from the node 17 to the node 23, causing the capacitive element 9 to be charged up to 2VDD, so that the voltage level at the node 23 becomes 2VDD. However, the voltage level at the node 23 does not vary because the operation in the no-loaded steady state is considered now and the capacitive element 9 has been charged up to 2VDD.

At time t6 and time t7, the state at time t5 is maintained. At time t8, the voltage level of the signal P1DD transitions from 3VDD to 2VDD. The gate-to-source voltage in the NMOS transistor 19 becomes 0V, so that the NMOS transistor 19 is turned off.

Since the voltage generator according to the present embodiment is configured as such, the reverse voltage applied to the PMOS transistors 12 and 13 can be made VDD similarly to the first preferred embodiment. Therefore, it is possible to prevent degradation of the PMOS transistors 12 and 13 in drive capability which would be caused by a large reverse voltage.

Further, the present embodiment achieves a simpler circuit configuration without using a cross connection used in the first preferred embodiment.

Although the signal P1D is set at 2VDD at the H level, a higher voltage may be applied in order to reduce the on-state resistance of the NMOS transistor 11. For instance, a voltage of 3VDD may be applied. The signal P1D is set at VDD at the L level, and the reverse voltage is a voltage applied between the node 16 and terminal 25 when the NMOS transistor 11 is in the off state, which is −VDD. To drop the reverse voltage, the signal P1D may be set at VDD+α at the L level. In that case, however, an off-margin (a margin for the reverse voltage necessary for holding the NMOS transistor 11 in the off state) of the NMOS transistor 11 is reduced.

Further, the signal P1DD is set at 3VDD at the H level, however, a voltage of, e.g., 4VDD may be applied, which allows the on-state resistance in the NMOS transistor 19 to be reduced. The signal P1DD may be set at 2VDD+α at the L level. In that case, the off-margin is reduced while the reverse voltage applied to the NMOS transistor 19 drops.

### Third Preferred Embodiment

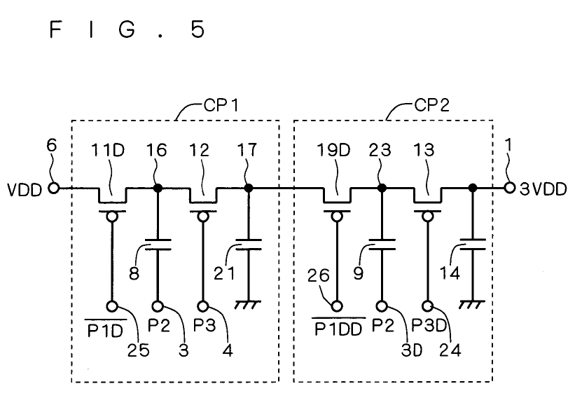

FIG. 5 is a circuit diagram illustrating the configuration of a voltage generator according to a third preferred embodiment. According to the present embodiment, the NMOS transistors 11 and 19 of the voltage generator according to the second preferred embodiment are replaced by PMOS transistors 11D and 19D, respectively.

A signal \overline{P1D} is input to the gate of the PMOS transistor 11D, and a signal \overline{P1DD} is input to the gate of the PMOS transistor 19D. The signal \overline{P1D} is set at 2VDD at the H level and 0V at the L level, and has an opposite polarity to the signal P1D shown in FIG. 4. More specifically, the voltage level of the signal \overline{P1D} is 2VDD (H level) during a period in which the voltage level of the signal P1D is VDD (L level). The voltage level of the signal \overline{P1D} is 0V (L level) during a period in which the voltage level of the signal P1D is 2VDD (H level).

The signal \overline{P1DD} is set at 3VDD at the H level and 0V at the L level, and has an opposite polarity to the signal P1DD shown in FIG. 4. More specifically, the voltage level of the signal \overline{P1DD} is 3VDD (H level) during a period in which the voltage level of the signal P1DD is 2VDD (L level). The voltage level of the signal \overline{P1DD} is 0V (L level) during a period in which the voltage level of the signal P1DD is 3VDD (H level).

The rest of the configuration is the same as that of the first preferred embodiment, and the same elements are indicated by the same reference characters, repeated explanation of which is thus omitted here. The operation of the voltage generator according to the present embodiment is the same as in the second preferred embodiment, repeated explanation of which is also omitted here.

In the present embodiment, the NMOS transistor 19 is replaced by the PMOS transistor 19D (see FIG. 3). As a result, a signal input to the gate of the PMOS transistor 19D can be varied between 0V and 3VDD. The gate-to-source voltage applied to the PMOS transistor 12 in the on state is 2VDD. Accordingly, the on-state current can be increased as compared to the second preferred embodiment in which the NMOS transistor 19 has a gate-to-source voltage of VDD in the on state.

### Fourth Preferred Embodiment

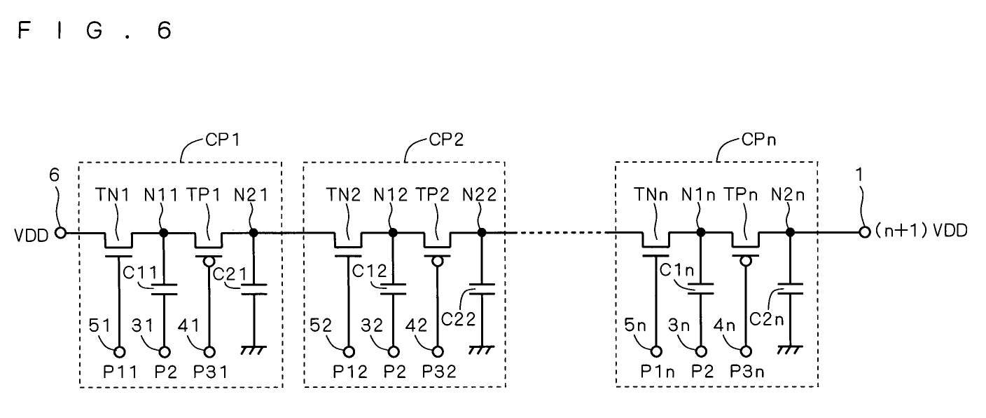

FIG. 6 is a circuit diagram illustrating the configuration of a voltage generator according to a sixth preferred embodiment. In the present embodiment, a plurality of (in the illustrated example, n pieces of) unit voltage generation circuits CP1 to CPn are connected in cascade.

The unit voltage generation circuit CP1 is configured as described hereinbelow. An NMOS transistor TN1 has its drain connected to the terminal 6 and its source connected to the source of a PMOS transistor TP1 and one end of a capacitive element C11 at a node N11. The capacitive element C11 has its other end connected to a terminal 31, to which the signal P2 is input.

The NMOS transistor TN1 has its gate connected to a terminal 51, to which a signal P11 is input.

The PMOS transistor TP1 has its drain connected to the drain of an NMOS transistor TN2 and one end of a capacitive element C21 at a node N21. The capacitive element C21 has its other end grounded. The PMOS transistor TP1 has its gate connected to a terminal 41, to which a signal P31 is input.

Next, the unit voltage generation circuit CP2 connected in cascade to the unit voltage generation circuit CP1 will be described. The NMOS transistor TN2 has its drain connected to the node N21 and its source connected to the source of a PMOS transistor TP2 and one end of a capacitive element C12 at a node N12. The capacitive element C12 has its other end connected to a terminal 32, to which the signal P2 is input.

The NMOS transistor TN2 has its gate connected to a terminal 52, to which a signal P12 is input.

The PMOS transistor TP2 has its drain connected to the drain of an NMOS transistor TN3 (not shown) and one end of a capacitive element C22 at a node N22. The capacitive element C22 has its other end grounded. The PMOS transistor TP2 has its gate connected to a terminal 42, to which a signal P32 is input. Similarly, unit voltage generation circuits CP3 to CPn−1 of similar configuration are connected in cascade.

The n-th unit voltage generation circuit CPn is connected to the unit voltage generation circuit CPn−1 (not shown). An NMOS transistor TNn has its drain connected to a node N2(n−1) (not shown) and its source connected to the source of a PMOS transistor TPn and one end of a capacitive element C1n at a node N1n. The capacitive element C1n has its other end connected to a terminal 3n, to which the signal P2 is input. The NMOS transistor TNn has its gate connected to a terminal 5n, to which a signal P1n is input.

The PMOS transistor TPn has its drain connected to one end of a capacitive element C2n at a node N2n. The capacitive element C2n has its other end grounded. The PMOS transistor TPn has its gate connected to a terminal 4n, to which a signal P3n is input. The node N2n is connected to the terminal 1.

The signals P11, P31, P12 and P32 respectively correspond to the signals P1D, P3, P1DD and P3D described in the second preferred embodiment, and have the same phase and the same voltage level as the corresponding signals. A signal having the same phase as the signal P1D and set at nVDD at the L level and (n+1)VDD at the H level is input to the terminal 5n of the unit voltage generation circuit CPn. A signal set at GND at the L level and (n+1)VDD at the H level is input to the terminal 4n.

In the steady state, the capacitive element C11 is charged up to VDD, and the capacitive element C21 is charged up to 2VDD. The capacitive element C12 is charged up to 2VDD, and the capacitive element C22 is charged up to 3VDD. The capacitive element C1n is charged up to nVDD, and the capacitive element C2n is charged up to (n+1)VDD.

The operation of each of the unit voltage generation circuits CP1 to CPn is the same as described in the second preferred embodiment, repeated explanation of which is thus omitted here.

Upon receipt of a voltage of VDD input to the terminal 6, the unit voltage generation circuit CP1 brings the voltage level at the node N21 to 2VDD. Upon receipt of the voltage of 2VDD input to the node N21, the unit voltage generation circuit CP2 brings the voltage level at the node N22 to 3VDD. Similarly, upon receipt of a voltage of nVDD, the unit voltage generation circuit CPn brings the voltage level at the node N2n to (n+1)VDD and outputs the voltage from the terminal 1.

In the present embodiment, a reverse voltage of VDD is applied to the NMOS transistors and PMOS transistors. For instance, a reverse voltage in the NMOS transistor TNn is expressed as: nVDD (voltage at terminal 5n)−(n+1)VDD (voltage at node N1n)=−VDD. A reverse voltage in the PMOS transistor TPn is expressed as: (n+1)VDD (voltage at terminal 4n)−nVDD (voltage at node N1n)=VDD.

As a result, the voltage generator according to the present embodiment is capable of generating a voltage of (n+1)VDD while preventing the NMOS transistors and PMOS transistors from being degraded in on-state current with time.

In the present embodiment, n pieces of unit voltage generation circuits of the same configuration as the unit voltage generation circuit CP1 described in the second preferred embodiment (see FIG. 3) are connected in cascade, however, n pieces of unit voltage generation circuits of the same configuration as the unit voltage generation circuit CP1 described in the third preferred embodiment (see FIG. 5) may be connected in cascade. Alternatively, the unit voltage generation circuits CP1 described in the second and third preferred embodiments may be combined.

### Fifth Preferred Embodiment

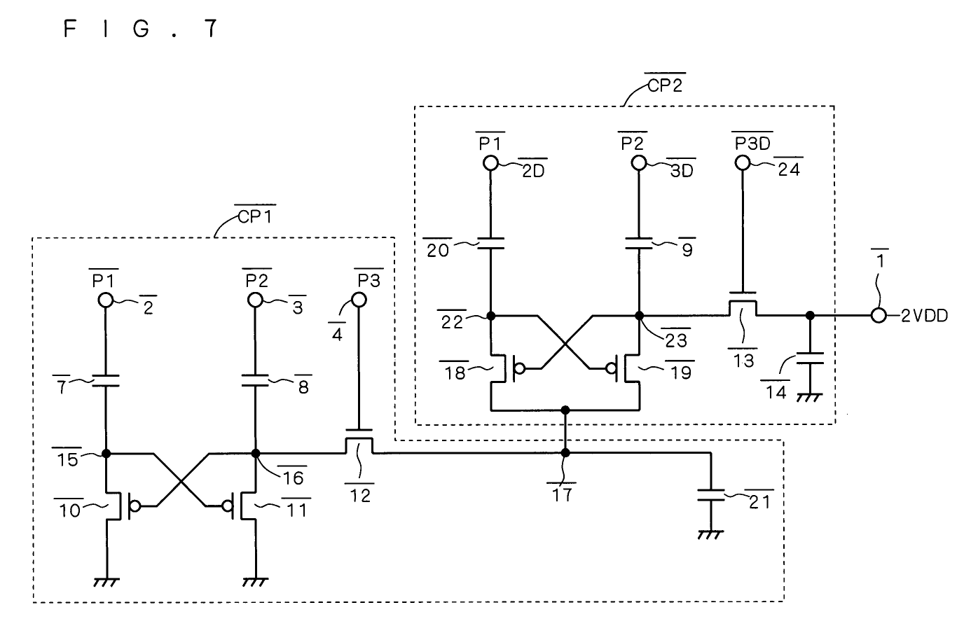

FIG. 7 is a circuit diagram illustrating the configuration of a voltage generator according to a fifth preferred embodiment. The voltage generator according to the present embodiment includes MOS transistors opposite in polarity to those of the voltage generator described in the first preferred embodiment.

As shown in FIG. 7, the voltage generator includes a unit voltage generation circuit \overline{CP1} and a unit voltage generation circuit \overline{CP2}. First, the configuration of the unit voltage generation circuit \overline{CP1} will be described. A PMOS transistor \overline{10} has its drain grounded and its source connected to the gate of a PMOS transistor \overline{11} and one end of a capacitive element \overline{7} at a node \overline{15}. The capacitive element \overline{7} has its other end connected to a terminal \overline{2}, to which a signal \overline{P1} is input.

The PMOS transistor \overline{11} has its drain grounded and its source connected to the gate of the PMOS transistor \overline{10} and one end of a capacitive element \overline{8} at a node \overline{16}. The capacitive element \overline{8} has its other end connected to a terminal \overline{3}, to which a signal \overline{P2} is input.

An NMOS transistor \overline{12} has its source connected to the node \overline{16} and its drain connected to one end of a capacitive element \overline{21} at a node \overline{17}. The capacitive element \overline{21} has its other end grounded. The NMOS transistor \overline{12} has its gate connected to a terminal \overline{4}, to which a signal \overline{P3} is input.

Next, the configuration of the unit voltage generation circuit \overline{CP2} will be described. Each of PMOS transistors \overline{18} and \overline{19} has its drain connected to the node \overline{17}. The PMOS transistor \overline{18} has its source connected to the gate of the PMOS transistor \overline{19} and one end of a capacitive element \overline{20} at a node \overline{22}. The capacitive element \overline{20} has its other end connected to a terminal \overline{2D}, to which the signal \overline{P1} is input.

The PMOS transistor \overline{19} has its source connected to the gate of the PMOS transistor \overline{18} and one end of a capacitive element \overline{9} at a node \overline{23}. The capacitive element \overline{9} has its other end connected to a terminal \overline{3D}, to which the signal \overline{P2} is input.

An NMOS transistor \overline{13} has its source connected to the node \overline{23} and its drain connected to the terminal \overline{1} and one end of a capacitive element \overline{14}. The capacitive element \overline{14} has its other end grounded. The NMOS transistor \overline{13} has its gate connected to a terminal \overline{24}, to which a signal \overline{P3D} is input.

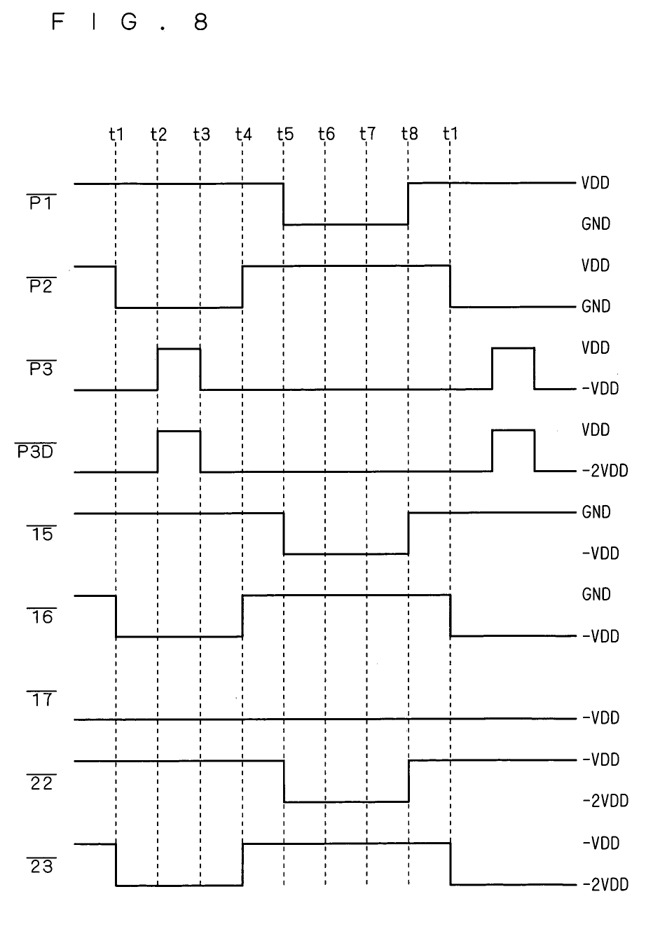

FIG. 8 is a timing chart of an operation of the voltage generator according to the present embodiment. The signal waveforms of the signals \overline{P1}, \overline{P2}, \overline{P3} and \overline{P3D} and voltage waveforms at the nodes \overline{15}, \overline{16}, \overline{17}, \overline{22} and \overline{23} are shown respectively.

For the sake of simplicity, an operation in the no-loaded steady state in which a voltage of −2VDD is output from the terminal \overline{1} will be described hereinbelow.

In the steady state, the capacitive elements \overline{7} and \overline{8} are charged up to VDD with reference to the voltage levels at the nodes \overline{15} and \overline{16}, respectively. The capacitive elements \overline{9} and \overline{20} are charged up to 2VDD with reference to the voltage levels of the nodes \overline{23} and \overline{22}, respectively. The capacitive element \overline{21} is charge up to −VDD with reference to GND. The capacitive element \overline{14} is charged up to −2VDD with reference to GND. FIG. 8 shows one period of each of the signals.

First, the operation of the unit voltage generation circuit \overline{CP1} will be described. At time t1, the signal \overline{P2} transitions from VDD to GND while the voltage level of the signal \overline{P1} is kept at VDD. At this time, the voltage level at the node \overline{16} drops from 0V to −VDD. When the voltage level at the node \overline{16} drops to −VDD, the gate-to-source voltage in the PMOS transistor \overline{10} becomes −VDD, so that the PMOS transistor \overline{10} transitions to the on state. As a result, the node \overline{15} is compensated for to 0V even when a leakage current causes a voltage drop at the node \overline{15}.

A voltage of 0V is applied to the gate of the NMOS transistor \overline{11}. The gate-to-source voltage in the PMOS transistor \overline{11} is VDD, and the PMOS transistor \overline{11} remains in the off state. Thus, a leakage current flows from GND to the node \overline{16} via the PMOS transistor \overline{11}, which can prevent the voltage level at the node \overline{16} from rising.

Next, at time t2, the voltage level of the signal \overline{P3} transitions from −VDD to VDD. The gate-to-source voltage in the NMOS transistor \overline{12} becomes 2VDD, and the NMOS transistor \overline{12} transitions from the off state to the on state. A load current normally flows from the capacitive element \overline{21} to the node \overline{16} via the NMOS transistor \overline{12}. Then, the capacitive element \overline{21} is charged up to −VDD. However, the load current does not flow because the operation in the no-loaded steady state is considered now and the capacitive element \overline{21} has been charged up to −VDD.

At time t3, the voltage level of the signal \overline{P3} transitions from VDD to −VDD. As a result, the gate-to-source voltage in the NMOS transistor \overline{12} becomes 0V, and the NMOS transistor \overline{12} transitions from the on state to the off state. Therefore, the voltage level at the node \overline{17} is kept at −VDD even when the voltage level at the node \overline{16} varies.

At time t4, the voltage level of the signal \overline{P2} transitions from GND to VDD, and the voltage level at the node \overline{16} transitions from −VDD to 0V. Since the NMOS transistor \overline{12} is in the off state, there is no possibility that current will flow from the node \overline{16} to the node \overline{17} via the NMOS transistor \overline{12} to cause a voltage drop at the node 17.

At time t5, the voltage level of the signal \overline{P1} transitions from VDD to GND. As the capacitive element \overline{7} has been charged up to VDD, the voltage level at the node \overline{15} transitions from 0V to −VDD. As a result, the gate-to-source voltage in the PMOS transistor \overline{11} becomes −VDD, and the PMOS transistor \overline{11} transitions to the on state. The node \overline{16} is grounded via the PMOS transistor \overline{11}.

At time t6 and time t7, the state at time t5 is maintained. At time t8, the voltage level of the signal \overline{P1} transitions from GND to VDD. The voltage level at the node \overline{15} transitions from −VDD to GND. The gate-to-source voltage in the PMOS transistor \overline{11} becomes VDD, and the PMOS transistor \overline{11} is turned off.

Now, the operation of the unit voltage generation circuit \overline{CP2} will be described. At time t1, the voltage level of the signal \overline{P2} drops from VDD to GND, then, the voltage level at the node \overline{23} drops from −VDD to −2VDD. When the voltage level at the node \overline{23} drops to −2VDD, the gate-to-source voltage in the PMOS transistor \overline{18} becomes −VDD, and the PMOS transistor \overline{18} transitions to the on state.

Since the voltage level at the node \overline{17} is −VDD, the voltage level at the node \overline{22} is also −VDD. Therefore, the voltage level at the node \overline{22} is compensated for to −VDD even when a leakage current causes a voltage rise at the node \overline{22}.

The gate of the PMOS transistor \overline{19} is connected to the node \overline{22}. Since the voltage level at the node \overline{22} is −VDD, the PMOS transistor \overline{19} is in the off state. Therefore, the voltage level at the node \overline{17} is kept at −VDD without fluctuations even when the voltage level at the node \overline{23} drops from −VDD to −2VDD.

Next, at time t2, the voltage level of the signal \overline{P3D} transitions from −2VDD to VDD. As a result, the gate-to-source voltage in the NMOS transistor \overline{13} becomes 3VDD, and the NMOS transistor \overline{13} transitions from the off state to the on state. A load current normally flows from the capacitive element \overline{14} to the node \overline{23} via the NMOS transistor \overline{13}. Then, the capacitive element \overline{14} is charged up to −2VDD. However, a load current does not flow because the operation in the no-loaded steady state is considered now and the capacitive element \overline{14} has been charged. Since the capacitive element \overline{14} is charged up to −2VDD, an output voltage of −2VDD is output from the terminal \overline{1}.

At time t3, the voltage level of the signal \overline{P3D} transitions from VDD to −2VDD. As a result, the gate-to-source voltage in the NMOS transistor \overline{13} becomes 0V, and the NMOS transistor \overline{13} transitions from the on state to the off state. Therefore, the voltage level at the terminal \overline{1} is kept at −2VDD even when the voltage level at the node \overline{23} varies.

At time t4, the voltage level of the signal \overline{P2} transitions from GND to VDD. Then, the voltage level at the node \overline{23} transitions from −2VDD to −VDD. A voltage of −2VDD is applied to the gate of the NMOS transistor \overline{13}, and the NMOS transistor \overline{13} is in the off state. Therefore, there is no possibility that current will flow from the node \overline{23} to the capacitive element \overline{14} via the NMOS transistor \overline{13} to cause a voltage drop at the terminal \overline{1}.

At time t5, the voltage level of the signal \overline{P1} transitions from VDD to GND. Since the capacitive element \overline{20} has been charged up to 2VDD, the voltage level at the node \overline{22} transitions from −VDD to −2VDD. As a result, the gate-to-source voltage in the PMOS transistor \overline{19} becomes −VDD, and the PMOS transistor \overline{19} transitions to the on state. The node \overline{23} is connected to the node \overline{17} via the PMOS transistor \overline{19}.

Accordingly, a load current normally flows from the node \overline{17} to the node \overline{23}, causing the capacitive element \overline{9} to be charged up to 2VDD, and the voltage level at the node \overline{23} becomes −VDD. However, the voltage level at the node \overline{23} does not vary because the operation in the no-loaded steady state is considered now and the capacitive element \overline{9} has been charged up to 2VDD.

Even when the voltage level at the node \overline{22} transitions from −VDD to −2VDD, there is no possibility that the voltage level at the node \overline{17} will vary because the PMOS transistor \overline{18} is in the off state.

At time t6 and time t7, the state at time t5 is maintained. At time t8, the voltage level of the signal \overline{P1} transitions from GND to VDD. The voltage level at the node \overline{22} transitions from −2VDD to −VDD. Then, the gate-to-source voltage in the PMOS transistor \overline{19} becomes VDD, and the PMOS transistor \overline{19} is turned off.

In the voltage generator according to the present embodiment, the PMOS transistors \overline{18} and \overline{19} are cross-connected, so that the voltage level at the node \overline{17} is kept at −VDD. The voltage level at the node \overline{16} ranges from 0V to −VDD. Therefore, the NMOS transistor \overline{12} can be turned off by applying a voltage of −VDD to the gate of the NMOS transistor \overline{12}. Then, the reverse voltage in the NMOS transistor \overline{12} is expressed as: −VDD (voltage at node \overline{16})−0 (voltage at node \overline{P3})=−VDD even when the voltage level at the node \overline{16} transitions to 0V.

Further, the voltage level at the terminal \overline{1} is kept at −2VDD, and the voltage level at the node \overline{23} ranges from −VDD to −2VDD. Therefore, the NMOS transistor \overline{13} can be turned off by applying a voltage of −2VDD to the gate. Then, when the voltage level at the node \overline{23} transitions to −VDD, the reverse voltage in the PMOS transistor \overline{13} is obtained by subtracting the voltage at the node \overline{23} from the gate voltage, that is, expressed as: −2VDD−(−VDD)=−VDD.

Since the reverse voltage applied to each of the NMOS transistors \overline{12} and \overline{13} is −VDD, it is possible to prevent degradation of the NMOS transistors \overline{12} and \overline{13} in drive capability which would be caused by a large reverse voltage.

For the sake of simplicity, it has been described above that the reference voltage is GND (0V) and the voltage amplitude of the signal \overline{P2} is VDD. Indicating the reference voltage as VR and the voltage amplitude of the signal \overline{P2} as VW, the output voltage V1 output from the terminal \overline{1} is generally expressed as V1=VR−2·VW. In the example shown in FIG. 7, the reference voltage VR is 0V and the voltage amplitude VW is VDD, and accordingly, the output voltage V1 becomes −2·VDD.

Further, in FIG. 7, the capacitive elements \overline{8} and \overline{9} serve to supply a load current. The signal \overline{P2} is thus required to have current drive capability. Therefore, for instance, the signal \overline{P2} is generated by a main power of an LSI with the H level set at VDD and the L level set at 0V.

The signals \overline{P1} and \overline{P2} may not necessarily be identical in voltage level. Further, the signals \overline{P1} and \overline{P2} are used for driving the capacitive elements \overline{20} and \overline{9}, respectively, however, other signals having the same phase relationship as that between the signals P1 and P2 may be used.

Furthermore, the number of unit voltage generation circuits may be increased to generate a lower output voltage without increasing the reverse voltage.

### Sixth Preferred Embodiment

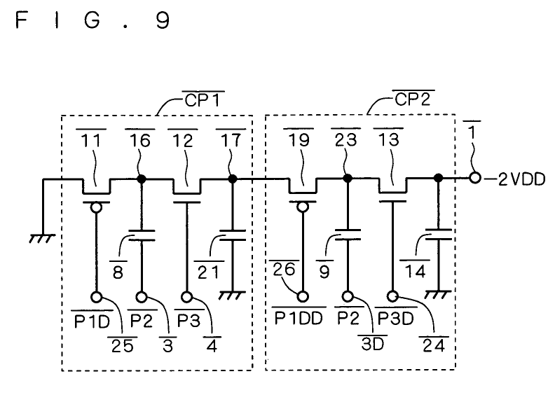

FIG. 9 is a circuit diagram illustrating the configuration of a voltage generator according to a sixth preferred embodiment. The voltage generator according to the present embodiment replaces the cross connection formed by the PMOS transistors \overline{10} and \overline{11} and that formed by the PMOS transistors \overline{18} and \overline{19} of the voltage generator according to the fifth preferred embodiment (see FIG. 7) by the PMOS transistors \overline{11} and \overline{19}, respectively.

A signal having the same voltage level as that applied in the fifth preferred embodiment is applied to the gate of each of the PMOS transistors \overline{11} and \overline{19}. More specifically, in the fifth preferred embodiment, the signal \overline{P1} transitions from VDD to GND so that a voltage which transitions from 0V to −VDD is applied to the gate of the PMOS transistor \overline{11}. Accordingly, the voltage generator according to the present embodiment is configured such that a signal \overline{P1D} having a voltage level which transitions from 0V to −VDD being in the same phase as the signal \overline{P1} is applied to the gate of the PMOS transistor \overline{11}. Similarly, a signal \overline{P1DD} having a voltage level which transitions from −VDD to −2VDD being in the same phase as the signal \overline{P1} is applied to the gate of the PMOS transistor \overline{19}. The rest of the configuration is the same as that of the fifth preferred embodiment, and the same elements are indicated by the same reference characters, repeated explanation of which is thus omitted here.

First, the unit voltage generation circuit \overline{CP1} according to the present embodiment will be described. The PMOS transistor \overline{11} has its drain grounded and its source connected to the source of the NMOS transistor \overline{12} and one end of the capacitive element \overline{8} at the node \overline{16}. The capacitive element \overline{8} has its other end connected to the terminal \overline{3}, to which the signal \overline{P2} is input. The PMOS transistor \overline{11} has its gate connected to a terminal \overline{25}, to which the signal \overline{P1D} is input.

The NMOS transistor \overline{12} has its drain connected to the drain of the PMOS transistor \overline{19} and one end of the capacitive element \overline{21} at the node \overline{17}. The capacitive element \overline{21} has its other end grounded. The PMOS transistor \overline{12} has its gate connected to the terminal \overline{4}, to which the signal \overline{P3} is input.

Next, the unit voltage generation circuit \overline{CP2} will be described. The PMOS transistor \overline{19} has its source connected to the source of the NMOS transistor \overline{13} and the one end of the capacitive element \overline{9} at the node \overline{23}. The capacitive element \overline{9} has its other end connected to a terminal \overline{3D}, to which the signal \overline{P2} is input. The PMOS transistor \overline{19} has its gate connected to a terminal \overline{26}, to which a signal \overline{P1DD} is input.

The NMOS transistor \overline{13} has its drain connected to the terminal \overline{1} and the one end of the capacitive element \overline{14}. The capacitive element \overline{14} has its other end grounded. The NMOS transistor \overline{13} has its gate connected to the terminal \overline{24}, to which the signal \overline{P3D} is input.

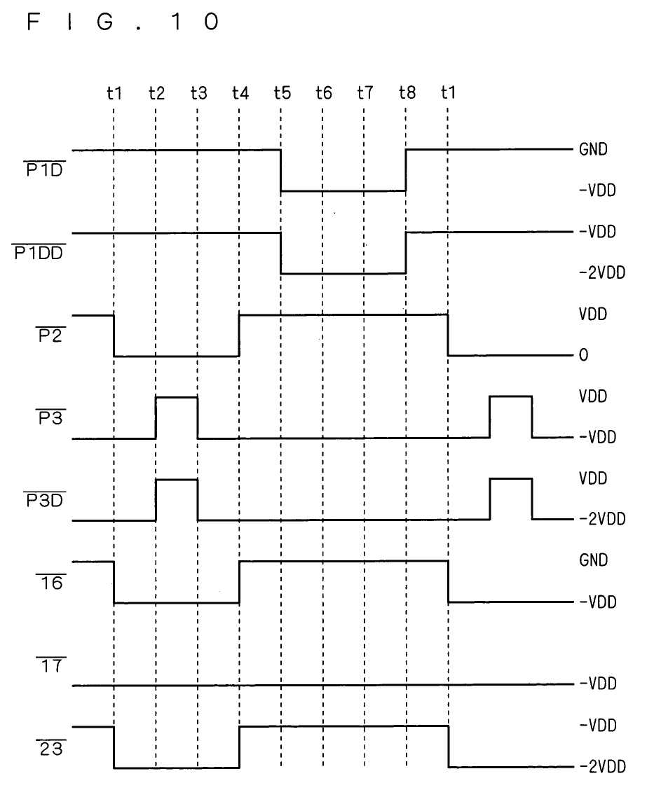

An operation of the voltage generator according to the present embodiment will now be described. FIG. 10 is a timing chart of the voltage generator according to present embodiment, showing the signal waveforms of the signals \overline{P1D}, \overline{P1DD}, \overline{P2}, \overline{P3} and \overline{P3D} and voltage waveforms at the nodes \overline{16}, \overline{17} and \overline{23}.

For the sake of simplicity, an operation in the no-loaded steady state in which a voltage of −2VDD is output from the terminal \overline{1} will be described hereinbelow. In the no-loaded steady state, the capacitive element \overline{8} is charged up to −VDD with reference to the voltage at the terminal \overline{3}. The capacitive element \overline{21} is charged up to −VDD with reference to GND. The capacitive element \overline{9} is charged up to −2VDD with reference to the voltage at the terminal \overline{3D}. The capacitive element \overline{14} is charged up to −2VDD with reference to GND. FIG. 10 shows one period of each of the signals.

First, the operation of the unit voltage generation circuit \overline{CP1} will be described. At time t1, the voltage level of the signal \overline{P2} drops from VDD to 0V. At this time, the voltage level at the node \overline{16} drops from 0V to −VDD. The signal \overline{P1D} having a voltage level of 0V is input to the gate of the PMOS transistor \overline{11} from the terminal \overline{25}. Then, the gate-to-source voltage in the PMOS transistor \overline{11} becomes VDD, and the PMOS transistor \overline{11} remains in the off state. Therefore, there is no possibility that a leakage current flows from GND to the node \overline{16} via the PMOS transistor \overline{11} to cause a voltage rise at the node \overline{16}.

Next, at time t2, the voltage level of the signal \overline{P3} transitions from −VDD to VDD. The gate-to-source voltage in the NMOS transistor \overline{12} becomes 2VDD, and the NMOS transistor \overline{12} transitions from the off state to the on state. A load current normally flows from the capacitive element \overline{21} to the capacitive element \overline{8} via the NMOS transistor \overline{12}. Then, the capacitive element \overline{21} is charged up to −VDD. However, a load current does not flow because the operation in the no-loaded steady state is considered now and the capacitive element \overline{21} has been charged up to −VDD.

At time t3, the voltage level of the signal \overline{P3} transitions from VDD to −VDD. As a result, the gate-to-source voltage in the NMOS transistor \overline{12} becomes 0V, and the NMOS transistor \overline{12} transitions from the on state to the off state. Therefore, the voltage level at the node \overline{17} is kept at −VDD even when the voltage level at the node \overline{16} varies.

At time t4, the voltage level of the signal \overline{P2} transitions from 0V to VDD, and the voltage level at the node \overline{16} transitions from −VDD to 0V. At this time, the signal \overline{P3D} having a voltage level of −VDD is input to the gate of the NMOS transistor \overline{12}, and thus, the NMOS transistor \overline{12} is in the off state. Therefore, there is no possibility that current will flow from the node \overline{16} to the node \overline{17} via the NMOS transistor \overline{12} to cause a voltage rise at the node \overline{17}.

At time t5, the voltage level of the signal \overline{P1D} transitions from GND to −VDD. Since the capacitive element \overline{8} is charged up to −VDD, the gate-to-source voltage in the PMOS transistor \overline{11} becomes −VDD, and the PMOS transistor \overline{11} transitions to the on state. The node \overline{16} is grounded via the PMOS transistor \overline{11}. Accordingly, a load current normally flows from the node \overline{16} to GND to charge the capacitive element \overline{8} up to −VDD, and the voltage level at the node \overline{16} becomes 0V. However, the voltage level at the node \overline{16} does not vary because the operation in the no-loaded steady state is considered now and the capacitive element \overline{8} has been charged up to −VDD.

At time t6 and time t7, the state at time t5 is maintained. At time t8, the voltage level of the signal \overline{P1D} transitions from −VDD to 0V. The gate-to-source voltage in the PMOS transistor \overline{11} becomes 0V, and the PMOS transistor \overline{11} is turned off.

Now, the operation of the unit voltage generation circuit \overline{CP2} will be described. At time t1, the voltage level of the signal \overline{P2} drops from VDD to GND, then, the voltage at the node \overline{23} drops from −VDD to −2VDD. Here, at time t1, the signal \overline{P1DD} input to the gate of the PMOS transistor \overline{19} has a voltage level of −VDD. The gate-to-source voltage in the PMOS transistor \overline{19} becomes VDD, and the PMOS transistor \overline{19} is turned off. Therefore, there is no possibility that a load current will flow from the node \overline{17} to the node \overline{23} via the PMOS transistor \overline{19} to cause a voltage rise at the node \overline{23}.

At time t2, the voltage level of the signal \overline{P3D} transitions from VDD to −2VDD. As a result, the gate-to-source voltage in the NMOS transistor \overline{13} becomes 3VDD, and the NMOS transistor \overline{13} transitions from the off state to the on state. A load current normally flows from the capacitive element \overline{14} to the node \overline{23} via the NMOS transistor \overline{13}. Then, the capacitive element \overline{14} is charged up to −2VDD. However, a load current does not flow because the operation in the no-loaded steady state is considered now and the capacitive element \overline{14} has been charged. Since the capacitive element \overline{14} has been charged up to −2VDD, a voltage of −2VDD is output from the terminal \overline{1}.

Next, at time t3, the voltage level of the signal \overline{P3D} transitions from VDD to −2VDD. As a result, the gate-to-source voltage in the NMOS transistor \overline{13} becomes 0V, and the NMOS transistor \overline{13} transitions from the on state to the off state. Therefore, the voltage level at the terminal \overline{1} is kept at −2VDD even when the voltage level at the node \overline{23} varies.

At time t4, the voltage level at the node \overline{23} transitions from −2VDD to −VDD. A voltage of −2VDD is applied to the gate of the NMOS transistor \overline{13}, and the NMOS transistor \overline{13} is in the off state. Therefore, there is no possibility that current will flow from the node \overline{23} to the terminal \overline{1} via the NMOS transistor \overline{13} to cause a voltage rise at the terminal \overline{1}.

At time t5, the voltage level of the signal \overline{P1DD} transitions from −VDD to −2VDD. Since the capacitive element \overline{9} has been charged to −2VDD, the reverse voltage in the PMOS transistor \overline{19} becomes −VDD, so that the PMOS transistor \overline{19} transitions to the on state. The node \overline{23} is connected to the node \overline{17} via the PMOS transistor \overline{19}. Accordingly, a load current normally flows from the node \overline{23} to the node \overline{17}, causing the capacitive element \overline{9} to be charged up to −2VDD, so that the voltage level at the node \overline{23} becomes −VDD. However, the voltage level at the node \overline{23} does not vary because the operation in the no-loaded steady state is considered now and the capacitive element \overline{9} has been charged up to −2VDD.

At time t6 and time t7, the state at time t5 is maintained. At time t8, the voltage level of the signal \overline{P1DD} transitions from −2VDD to −VDD. The gate-to-source voltage in the PMOS transistor \overline{19} becomes 0V, so that the PMOS transistor \overline{19} is turned off.

Since the voltage generator according to the present embodiment is configured as such, the reverse voltage applied to each of the NMOS transistors \overline{12} and \overline{13} can be made VDD similarly to the fifth preferred embodiment, it is possible to prevent degradation of the NMOS transistors \overline{12} and \overline{13} in drive capability which would be caused by a large reverse voltage. Further, the present embodiment achieves a simpler circuit configuration without using cross connections employed in the fifth preferred embodiment.

### Seventh Preferred Embodiment

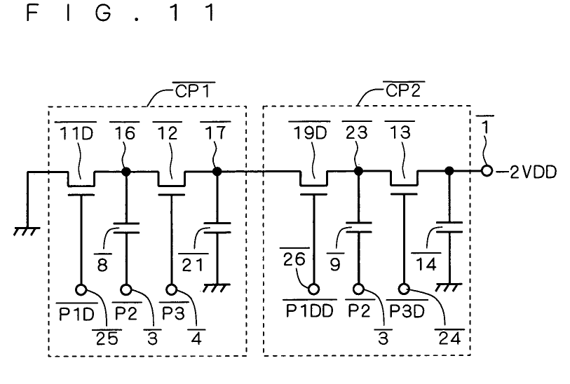

FIG. 11 is a circuit diagram illustrating the configuration of a voltage generator according to a seventh preferred embodiment. The voltage generator according to the present embodiment replaces the PMOS transistors \overline{11} and \overline{19} of the voltage generator according to the sixth preferred embodiment by PMOS transistors \overline{11D} and \overline{19D}, respectively. The signal \overline{P1D} is input to the gate of the NMOS transistor \overline{11D}, and the signal \overline{P1DD} is input to the gate of the NMOS transistor \overline{19D}. The rest of the configuration is the same as that shown in FIG. 9, and the same elements are indicated by the same reference characters, repeated explanation of which is thus omitted here.

The operation of the voltage generator according to the present embodiment is the same as in the sixth preferred embodiment, repeated explanation of which is also omitted here.

In the present embodiment, the NMOS transistor \overline{19D} is used instead of the PMOS transistor \overline{19} (see FIG. 6). As a result, a signal set at VDD at the H level and −2VDD at the L level can be input to the gate of the NMOS transistor \overline{19D} Accordingly, the gate-to-source voltage in the NMOS transistor \overline{19D} becomes 2VDD in the on state. Therefore, the on-state current can be increased as compared to the sixth preferred embodiment in which the reverse voltage in the PMOS transistor \overline{19} in the on state is VDD.

### Eighth Preferred Embodiment

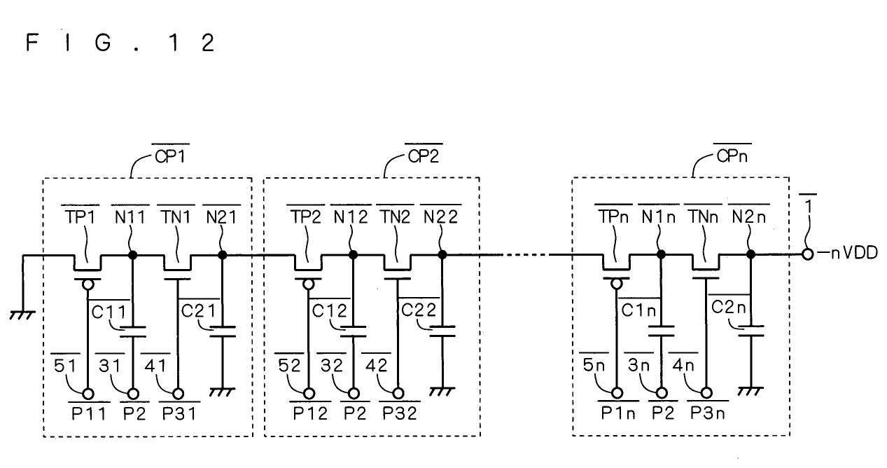

FIG. 12 is a circuit diagram illustrating the configuration of a voltage generator according to an eighth preferred embodiment. In the present embodiment, a plurality of (in the illustrated example, n pieces of) unit voltage generation circuits \overline{CP1} to \overline{CPn} connected in cascade.

The unit voltage generation circuit \overline{CP1} is configured as described hereinbelow. A PMOS transistor \overline{TP1} has its drain grounded and its source connected to the source of an NMOS transistor \overline{TN1} and one end of a capacitive element \overline{C11} at a node \overline{N11}. The capacitive element \overline{C11} has its other end connected to a terminal \overline{31}, to which the signal \overline{P2} is input. The PMOS transistor \overline{TP1} has its gate connected to a terminal \overline{51}, to which a signal \overline{P11} is input.

The NMOS transistor \overline{TN1} has its drain connected to the drain of a PMOS transistor \overline{TP2} and one end of a capacitive element \overline{C21} at a node \overline{N21}. The capacitive element \overline{C21} has its other end grounded. The NMOS transistor \overline{TN1} has its gate connected to a terminal \overline{41}, to which a signal \overline{P31} is input.

Next, the unit voltage generation circuit \overline{CP2} connected in cascade to the unit voltage generation circuit \overline{CP1} will be described. The PMOS transistor \overline{TP2} has its drain connected to the node \overline{N21} and its source connected to the source of an NMOS transistor \overline{TN2} and one end of a capacitive element \overline{C12} at a node \overline{N12}. The capacitive element \overline{C12} has its other end connected to a terminal \overline{32}, to which the signal \overline{P2} is input.

The PMOS transistor \overline{TP2} has its gate connected to a terminal \overline{52}, to which a signal \overline{P12} is input. The NMOS transistor \overline{TN2} has its drain connected to the drain of a PMOS transistor \overline{TP3} (not shown) and one end of a capacitive element \overline{C22} at a node \overline{N22}. The capacitive element \overline{C22} has its other end grounded. The NMOS transistor \overline{TN2} has its gate connected to a terminal \overline{42}, to which a signal \overline{P32} is input.

Similarly, unit voltage generation circuits \overline{CP3} to \overline{CPn−1}(not shown) of similar configuration are connected in cascade. The n-th unit voltage generation circuit \overline{CPn} is connected to the unit voltage generation circuit \overline{CPn−1}. A PMOS transistor \overline{TPn} has its drain connected to the source of an NMOS transistor \overline{TNn} and one end of a capacitive element \overline{C1n} at a node \overline{N1n}. The capacitive element \overline{C1n} has its other end connected to a terminal \overline{3n}, to which the signal \overline{P2} is input.

The PMOS transistor \overline{TPn} has its gate connected to a terminal \overline{5n}, to which a signal \overline{P1n} is input. The NMOS transistor \overline{TNn} has its drain connected to one end of a capacitive element \overline{C2n} at a node \overline{N2n}. The capacitive element \overline{C2n} has its other end grounded. The NMOS transistor \overline{TNn} has its gate connected to a terminal \overline{4n}, to which a signal \overline{P3n} is input. The node \overline{N2n} is connected to the terminal \overline{1}.

The signals \overline{P11}, \overline{P31}, \overline{P12} and \overline{P32} respectively correspond to the signals \overline{P1D}, \overline{P3}, \overline{P1DD} and \overline{P3D} described in the sixth preferred embodiment, and have the same phase and the same voltage level as the corresponding signals.

A signal having the same phase as the signal \overline{P1D} set at −nVDD at the L level and −(n−1)VDD at the H level is input to the terminal \overline{5n} of the unit voltage generation circuit \overline{CPn}.

A signal set at −nVDD at the L level and VDD at the H level is input to the terminal \overline{4n}.

In the steady state, the capacitive element \overline{C11} is charged up to −VDD, and the capacitive element \overline{C21} is charged up to −VDD. The capacitive element \overline{C12} is charged up to −2VDD, and the capacitive element \overline{C22} is charged up to −2VDD. The capacitive element \overline{C1n} is charged up to −nVDD, and the capacitive element \overline{C2n} is charged up to −nVDD.

The operation of each of the unit voltage generation circuits \overline{CP1} to \overline{CPn} is the same as described in the fifth preferred embodiment, repeated explanation of which is thus omitted here.

The unit voltage generation circuit \overline{CP1} brings the voltage level at the node \overline{N21} to −VDD. Upon receipt of a voltage of −VDD input from the node \overline{N21}, the unit voltage generation circuit \overline{CP2} brings the voltage level at the node \overline{N22} to −2VDD. Similarly, upon receipt of a voltage of −(n−1)VDD, the unit voltage generation circuit \overline{CPn} brings the voltage level at the node \overline{N2n} to −nVDD, and outputs the voltage from the terminal \overline{1}.

In the present embodiment, the reverse voltage of each of the MOS transistors is VDD. Therefore, in the present embodiment, connecting n pieces of unit voltage generation circuits in cascade allows a voltage of −nVDD to be generated while keeping the reverse voltage applied to the transistors at VDD.

The voltage generator according to the present embodiment is configured such that the n pieces of unit voltage generation circuits described in the sixth preferred embodiment are connected in cascade, however, the n pieces of unit voltage generation circuits described in the seventh preferred embodiment may be connected in cascade. Alternatively, the configuration of the sixth preferred embodiment and that of the seventh preferred embodiment may be combined together.

While the invention has been shown and described in detail, the foregoing description is in all aspects illustrative and not restrictive. It is therefore understood that numerous modifications and variations can be devised without departing from the scope of the invention.

What is claimed is:

1. A voltage generator comprising
a plurality of unit voltage generation circuits connected in cascade, wherein
one of said plurality of unit voltage generation circuits includes:
a first field effect transistor having one terminal to which an input voltage is input;
a first capacitive element having one end connected to the other terminal of said first field effect transistor;
a second field effect transistor having one terminal connected to said one end of said first capacitive element; and
a second capacitive element having one end connected to the other terminal of said second field effect transistor from which an output voltage is output.

2. The voltage generator according to claim 1, wherein
said first field effect transistor and said second field effect transistor have the same conductivity type.

3. The voltage generator according to claim 1, wherein
said first field effect transistor and said second field effect transistor have opposite conductivity types.

4. The voltage generator according to claim 1, wherein
said plurality of unit voltage generation circuits include:
a first unit voltage generation circuit in which said first field effect transistor and said second field effect transistor have the same conductivity type; and
a second unit voltage generation circuit in which said first field effect transistor and said second field effect transistor have opposite conductivity types.

5. The voltage generator according to claim 1, further comprising
a third field effect transistor being cross-connected to said first field effect transistor.

6. The voltage generator according to claim 1, wherein
said second capacitive element has the other end connected to a terminal to which a predetermined voltage is applied.

7. A voltage generator comprising:
a first field effect transistor having one terminal to which an input voltage is input;
a first capacitive element having one end connected to the other terminal of said first field effect transistor;
a second field effect transistor having one terminal connected to said one end of said first capacitive element;
a second capacitive element having one end connected to the other terminal of said second field effect transistor from which an output voltage is output; and
a third field effect transistor being cross-connected to said first field effect transistor, wherein
said second field effect transistor when conducting carries a voltage between a control terminal and said one terminal thereof having an absolute value almost equal to an absolute value of said output voltage.
